(19) United States
(12) Patent Application Publication
(10) Pub. No.: US 2020/0135996 A1
(43) Pub. Date: Apr. 30, 2020

(54) LED MOUNTING METHOD AND DEVICE

(71) Applicant: ASTI GLOBAL INC., TAIWAN, Changhua County (TW)

(72) Inventor: CHIEN-SHOU LIAO, NEW TAIPEI CITY (TW)

(21) Appl. No.: 16/409,725

(22) Filed: May 10, 2019

(30) Foreign Application Priority Data
Oct. 31, 2018 (TW) 107138615

(51) Int. Cl. H01L 33/62; H01L 25/075; H01L 33/06; H01L 33/32; H01L 33/30; H01L 23/00; H01L 21/67; B65G 47/91

(52) U.S. Cl. CPC H01L 33/62; H01L 2224/81815; H01L 33/06; H01L 33/32; H01L 33/30; H01L 24/16; H01L 24/75; H01L 24/81; H01L 21/67132; B65G 47/91; H01L 2933/0066; H01L 2924/12041; H01L 2224/16157; H01L 2224/75263; H01L 2224/75745; H01L 2224/81224; H01L 25/0753

(57) ABSTRACT

A mounting method and a mounting device for an LED chip are provided. The mounting method includes: providing a circuit substrate; disposing a plurality of conductors on the conductive solder pads; disposing the plurality of LED chips on the circuit substrate; and directing a laser source generated by a laser source generation module to each LED chip, so that the laser source passes through the LED chip and is projected on at least two conductors. The conductor disposed between the LED chip and the circuit substrate is cured by irradiation of the laser source so that the LED chip is mounted on the circuit substrate. Thereby, the conductor can be cured by the irradiation of the laser source passing through the LED chip, so that the LED chip is mounted on the circuit substrate.

This application claims the benefit of priority to Taiwan Patent Application No. 107138615, filed on Oct. 31, 2018. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a chip mounting method and device, and more particularly to an LED mounting method and device.

### BACKGROUND OF THE DISCLOSURE

Light-emitting diodes (LEDs) are widely used nowadays due to their excellent light quality and high luminous efficiency. In general, a conventional LED display device uses a combination of red, green, and blue LED chips to form a full-color LED display device, so as to have better color performance. The full-color LED display device can respectively emit three colors of red, green and blue light by red, green and blue LED chips, and then form a full-color light by mixing light to display relevant information. However, during the conventional process of mounting the LED chip on a circuit substrate, a substrate carrying the LED chip needs to be removed first.

### SUMMARY OF THE DISCLOSURE

In response to the above-referenced technical inadequacies, the present disclosure provides an LED mounting method and device.

In one aspect, the present disclosure provides an LED mounting method including: firstly, providing a circuit substrate which includes a plurality of conductive solder pads; disposing a plurality of conductors on the conductive solder pads, respectively; disposing a plurality of LED chips on the circuit substrate, each of the LED chips being disposed on at least two of the conductors; directing a laser source generated by a laser source generation module to each of the LED chips, such that the laser source passes through the LED chip and is projected on at least two of the conductors; curing the conductor disposed between the LED chip and the circuit substrate by irradiation of the laser source, so that the LED chip is mounted on the circuit substrate.

In one aspect, the present disclosure provides an LED mounting device including a carrier module, a pick and place module, and a laser source generation module. The carrier module is configured to carry a circuit substrate which includes a plurality of conductive solder pads, and a plurality of conductors that are respectively disposed on the conductive solder pads. The pick and place module is configured to dispose a plurality of LED chips on the circuit substrate, and each of the LED chips is disposed on at least two of the conductors. A laser source generated by the laser source generation module is directed to each of the LED chips such that the laser source passes through the LED chip and is projected on at least two of the conductors. The conductor disposed between the LED chip and the circuit substrate is cured by irradiation of the laser source, so that the LED chip is mounted on the circuit substrate.

In another aspect, the present disclosure provides an LED mounting device, including mounting device a carrier module, a pick and place module, and a laser source generation module. A laser source generated by the laser source generation module is directed to an LED chip, so that the laser source passes through the LED chip and is projected on at least two conductors. The conductor is cured by irradiation of the laser source such that the LED chip is mounted on a circuit substrate.

Therefore, one of the beneficial effects of the present disclosure is that, by the technical features of “providing a circuit substrate including a plurality of conductive solder pads”, “a plurality of conductors being respectively disposed on the conductive solder pads”, “a plurality of LED chips being disposed on the circuit substrate, and each of the LED chips being disposed on at least two of the conductors”, “a laser source generated by a laser source generation module being directed to each of the LED chips, such that the laser source passes through the LED chip and is projected on at least two of the conductors”, and “the conductor disposed between the LED chip and the circuit substrate being cured by irradiation of the laser source”, the LED chip can be mounted on the circuit substrate.

Another beneficial effect of the present disclosure is that, by the technical features of “a carrier module for carrying a circuit substrate, and the circuit substrate includes a plurality of conductive solder pads, and a plurality of conductors that are respectively disposed on the conductive solder pads”, “a laser source generation module, the generated laser source is directed to each of the LED chips, such that the laser source passes through the LED chip and is projected on at least two of the conductors” and “the conductor disposed between the LED chip and the circuit substrate are cured by irradiation of the laser source”, the LED chip can be mounted on the circuit substrate.

Yet another beneficial effect of the present disclosure is that, by the technical features of “a mounting device including a carrier module, a pick and place module, and a laser source generation module” and “a laser source generated by the laser source generation module being directed to an LED chip, so that the laser source passes through the LED chip and is projected on at least two conductors, and the conductor is cured by irradiation of the laser source”, the LED chip can be mounted on the circuit substrate.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a flowchart of an LED mounting method according to a first embodiment of the present disclosure.

FIG. 2 is a schematic view of step S200 of the LED mounting method according to the first embodiment of the present disclosure.

FIG. 3 is a schematic view of step S201 of the LED mounting method according to the first embodiment of the present disclosure.

FIG. 4 is a schematic view of step S202 of the LED mounting method according to the first embodiment of the present disclosure.

FIG. 5 is a schematic view of step S203 of the LED mounting method according to the first embodiment of the present disclosure.

FIG. 6 is an enlarged schematic view of VI of FIG. 5.

FIG. 7 is a first schematic view of a laser source irradiation range in step S203 of the LED mounting method according to the first embodiment of the present disclosure.

FIG. 8 is a second schematic view of a laser source irradiation range in step S203 of the LED mounting method according to the first embodiment of the present disclosure.

FIG. 9 is a schematic view of step S204 of the LED mounting method according to the first embodiment of the present disclosure.

FIG. 10 is a first schematic view of step S205 of the LED mounting method according to the first embodiment of the present disclosure.

FIG. 11 is a second schematic view of step S205 of the LED mounting method according to the first embodiment of the present disclosure.

FIG. 12 is a schematic view of a detecting step of an LED mounting method according to the first embodiment of the present disclosure.

FIG. 13 is a block diagram of the LED mounting device according to the present disclosure.

FIG. 14 is a first schematic view of the LED mounting method according to a second embodiment of the present disclosure.

FIG. 15 is a second schematic view of the LED mounting method according to the second embodiment of the present disclosure.

FIG. 16 is a first schematic view of the LED mounting method according to a third embodiment of the present disclosure.

FIG. 17 is a second schematic view of the LED mounting method according to the third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

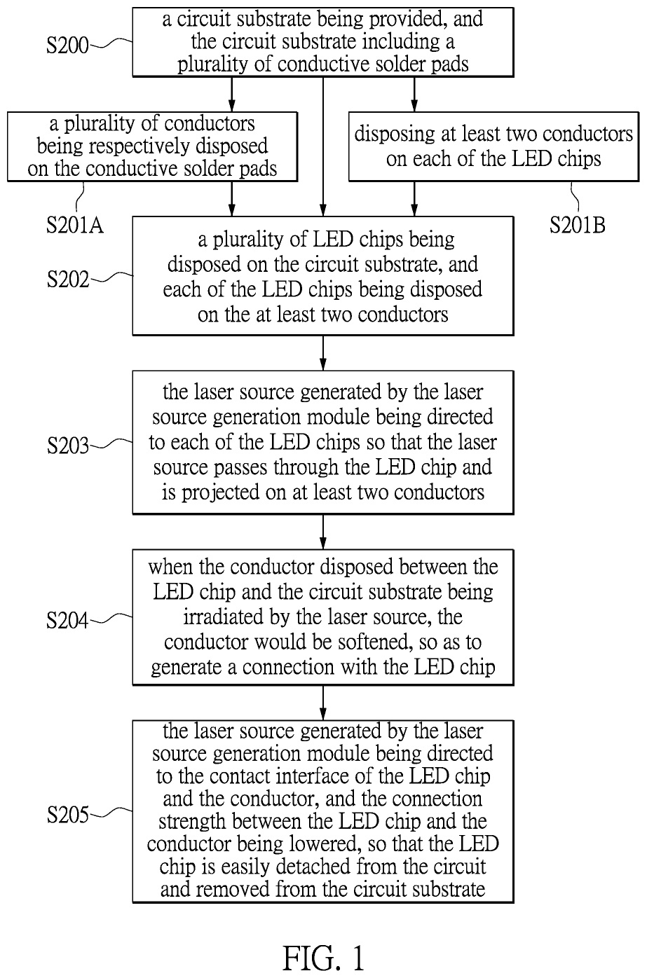

Referring to FIG. 1 to FIG. 12, a first embodiment of the present disclosure provides an LED mounting method, including the following steps:

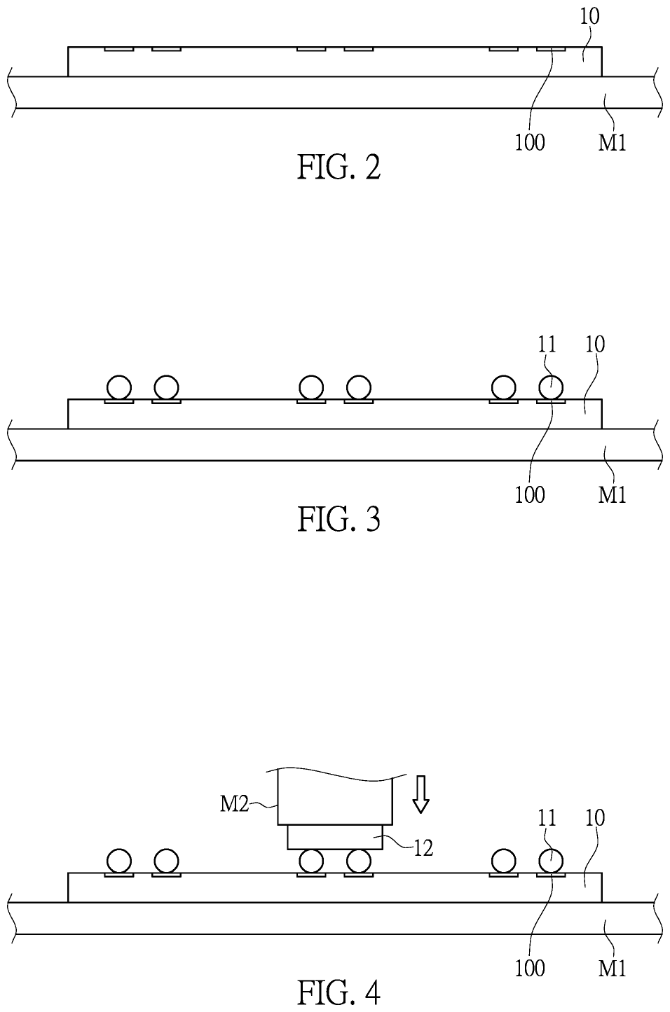

Firstly, as shown in FIG. 1 and FIG. 2, a circuit substrate 10 is provided, and the circuit substrate 10 includes a plurality of conductive solder pads 100 (step S200). For example, in step S200 of the present disclosure, a circuit substrate 10 can be carried by a carrier module M1, and the circuit substrate 10 further includes a plurality of conductive solder pads 100. The carrier module M1 can be a stage device with a displacement function. However, the present disclosure is not limited thereto.

Further, as shown in FIG. 1 and FIG. 3, after the step S200 of providing the circuit substrate 10, the present disclosure further includes: a plurality of conductors 11 that are respectively disposed on the conductive solder pads 100 (step S201A). For example, in step S201A of the present disclosure, at least one conductor 11 may be disposed on each of the conductive solder pads 100, and the conductor 11 may be a solder ball or other structures made of a conductive material. However, the present disclosure is not limited thereto.

Secondly, as shown in FIG. 1, FIG. 3 and FIG. 4, a plurality of LED chips 12 are disposed on the circuit substrate 10, and each of the LED chips 12 is disposed on the at least two conductors 11 (step S202).

For example, as shown in FIG. 1, FIG. 3 and FIG. 4, in step S202 of the present disclosure, a plurality of LED chips 12 are placed on the circuit substrate 10 by the pick and place module M2, and each of the LED chips 12 corresponds to the at least two conductors 11. The pick and place module M2 can be a vacuum nozzle or any kind of pick and place machine. However, the present disclosure is not limited thereto.

Thirdly, as shown in FIG. 1 and FIG. 5 to FIG. 8, a laser source L generated by a laser source generation module M3 is directed to each of the LED chips 12 so that the laser source L passes through the LED chip 12 and is projected on the at least two conductors 11 (step S203).

For example, as shown in FIG. 1 and FIG. 5 to FIG. 8, the present disclosure generates a laser source L through a laser source generation module M3 and is directed to each of the LED chips 12 after step S202. When the laser source L is projected on the LED chip 12, it passes through an n-type conductive layer N, an light-emitting layer M and a p-type conductive layer P of the LED chip 12, so as to be projected on the at least two conductors 11 of the circuit substrate 10. Further, as shown in FIG. 6, each of the LED chips 12 may be a micro-semiconductor light-emitting element (Micro LED) including the n-type conductive layer N, the light-emitting layer M through which the laser light source L passes, and the p-type conductive layer P that are disposed in a stacked arrangement. The n-type conductive layer N may be an n-type gallium nitride material layer or an n-type gallium arsenide material layer, the light-emitting layer M may be a multi-quantum well structure layer, and the p-type conductive layer P may be a p-type gallium nitride material layer or p-type gallium arsenide material layer, but present disclosure is not limited thereto. However, the above-mentioned examples are only one of the embodiments and the present disclosure is not limited thereto.

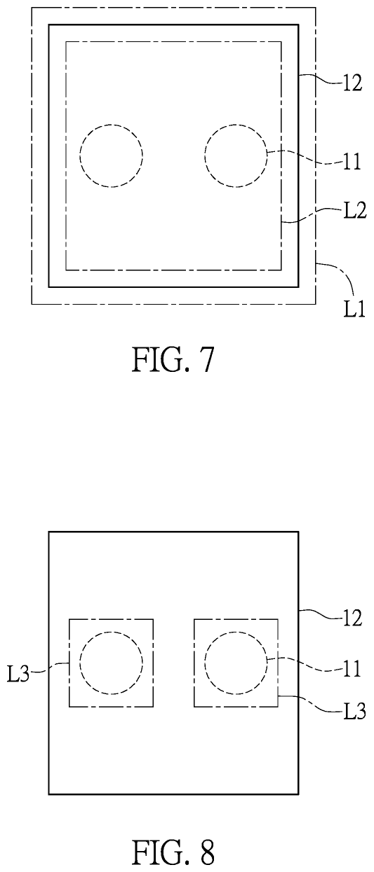

Furthermore, as shown in FIG. 7 and FIG. 8, the irradiation area of the laser source L only covers one conductor 11 or one LED chip 12, and the intensity of the laser source L generated by the laser source generation module M3 can be adjusted. The laser source L does not pass through the circuit substrate 10, but only passes through the LED chip 12. For example, in the present disclosure, by adjusting the intensity of the laser source L generated by the laser source generation module M3, the laser source L is projected on the conductor 11 through the LED chip 12, and the irradiation range of the laser source L can be in various configurations. For example, as shown in FIG. 7, the irradiation area of the laser source L1 may cover one LED chip 12, or the irradiation area of the laser source L2 may cover the at least two conductors 11; or, as shown in FIG. 8, the irradiation area of the laser source L3 may cover only one conductor 11. Moreover, in present disclosure, by adjusting the laser source generation module M3, the laser source L3 generated by the laser source generation module M3 passes through only the LED chip 12 and does not pass through the circuit substrate 10. However, the above-mentioned examples are only one of the embodiments and the present disclosure is not limited thereto.

Finally, as shown in FIG. 1 and FIG. 4 to FIG. 9, the conductor 11 disposed between the LED chip 12 and the circuit substrate 10 is cured by irradiation of the laser source L, so that the LED chip 12 is mounted on the circuit substrate 10 (step S204).

For example, as shown in FIG. 1 and FIG. 4 to FIG. 9, in step S204 of the present disclosure, when the conductor 11 disposed between the LED chip 12 and the circuit substrate 10 is irradiated by the laser source L, the conductor 11 would be softened, so as to generate a connection with the LED chip 12. Then, after the conductor 11 is cured, the LED chip 12 is mounted on the circuit substrate 10 and electrically connected to the circuit substrate 10 through the conductor 11.

It should be noted that, as shown in FIG. 1 and FIG. 9 to FIG. 11, after the step of the LED chip being mounted on the circuit substrate (step S204), the method further includes: directing the laser source L generated by the laser source generation module M3 to the contact interface F of the LED chip 12 and the conductor 11, such that the connection strength between the LED chip 12 and the conductor 11 is lowered, and the LED chip 12 is easily detached from the conductor 11 and removed from the circuit substrate 10 (step S205).

For example, as shown in FIG. 1 and FIG. 9 to FIG. 11, after the step S204 of the present disclosure, the laser source L generated by the laser source generation module M3 can be directed to the contact interface F between the LED chip 12 and the cured conductor 11 to soften part of the conductor 11 that is close to the contact interface F. Therefore, the connection strength and bonding force between the LED chip 12 and the conductor 11 are reduced, so that the LED chip 12 can be easily removed from the circuit substrate 10 without being separated from the conductor 11.

Then, as shown in FIG. 11, the at least two conductors 11 previously separated from the LED chip 12 can be removed from the circuit substrate 10 using a special instrument (such as a scraper or a grinder), so that new conductors 11 can later be replaced thereon. However, the present disclosure is not limited thereto.

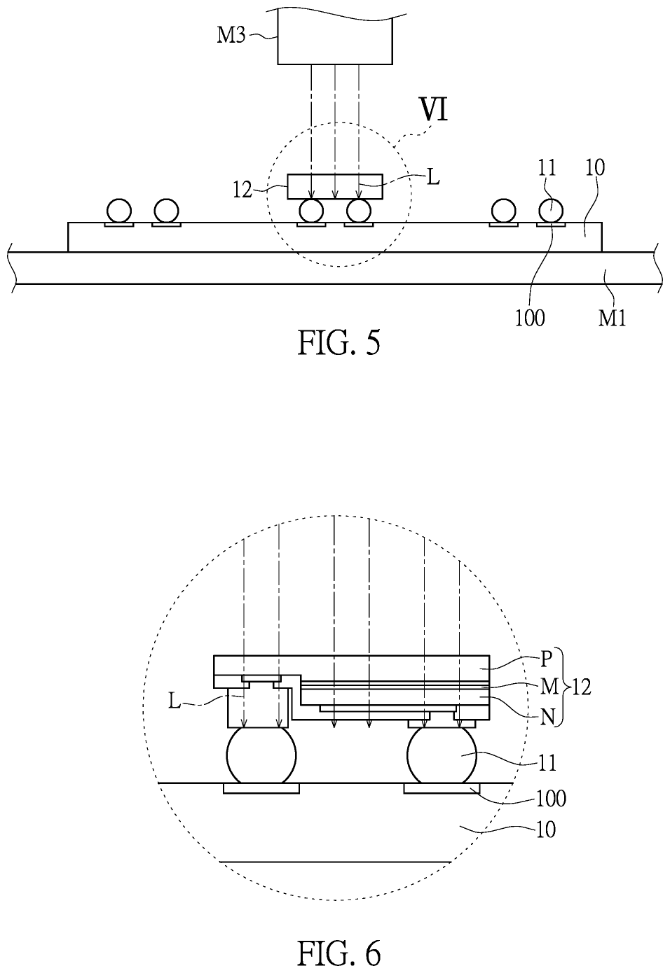

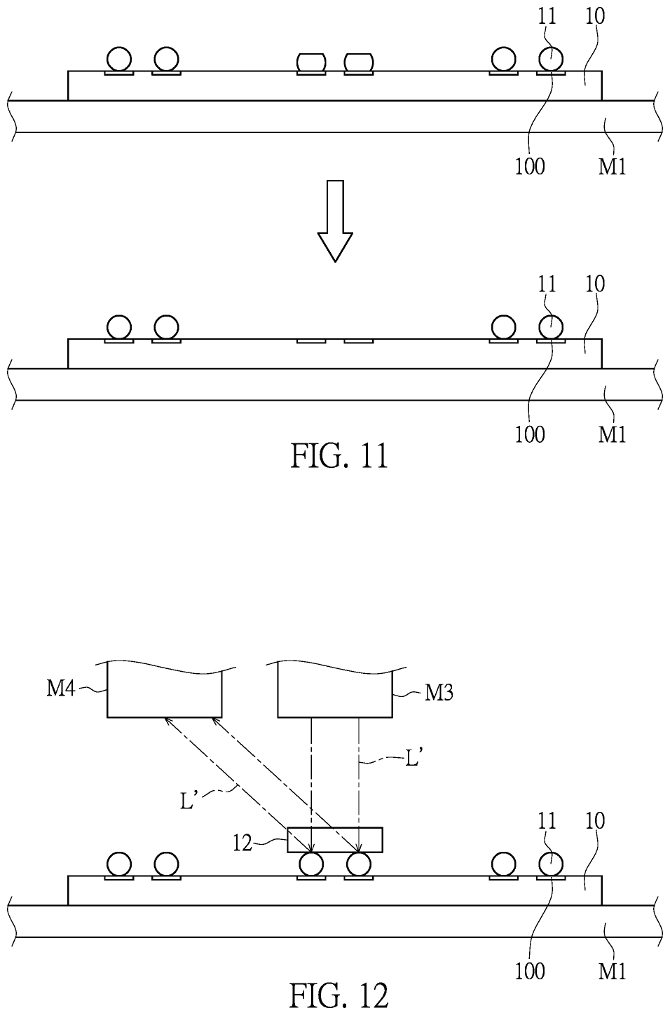

In addition, as shown in FIG. 1, FIG. 5 and FIG. 12, the laser source L generated by the laser source generation module M3 is directed to each of the LED chips 12 so that the laser source L passes through the LED chip 12 and is projected on at least two conductors 11 (step S203), the method further including: using a position detection module M4 to detect the position of the at least one conductor 11 (i.e., the detecting step); then, directing the laser source L generated by the laser source generation module M3 to the LED chip 12, so that the laser source L passes through the LED chip 12 and is projected on the at least two conductors 11. For example, as shown in FIG. 12, the position detection module M4 includes at least one receiving element for receiving a detection wave L′, and the detection wave L′ may be a laser source generation module M3. However, the present disclosure is not limited thereto.

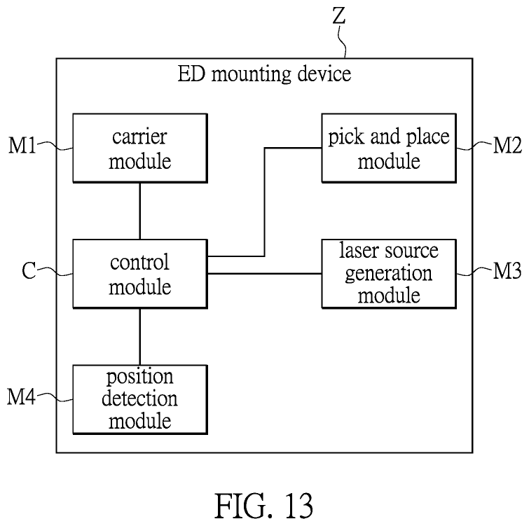

Furthermore, as shown in FIG. 12 and FIG. 13, the LED mounting method and device of the present disclosure can further be electrically connected to the carrier module M1, the pick and place module M2, the laser source generation module M3, and the position detection module M4 through a control module C. The control module C can drive each module to operate according to the built-in program or the control of the operator. However, the above-mentioned examples are only one of the embodiments and the present disclosure is not limited thereto.

Further, as shown in FIG. 10 and FIG. 12, the laser source L generated by the laser source generation module M3 is directed to the contact interface F of the LED chip 12 and the cured conductor 11, thereby reducing the connection strength between the LED chip 12 and the conductor 11. The step of removing the LED chip 12 from the circuit substrate 10 (step S102), further including: using the position detection module M4 to detect the position of the contact interface F of the LED chip 12 and the cured conductor 11 (i.e., the detecting step); then, directing the laser source L generated by the laser source generation module M3 to the contact interface F between the LED chip 12 and the cured conductor 11 to reduce the connection strength between the LED chip 12 and the conductor 11. For example, as shown in FIG. 12, the position detection module M4 includes the at least one receiving element for receiving a detection wave L′, and the detection wave L′ can be provided by the laser source generation module M3. However, the present disclosure is not limited thereto.

It should be noted that, in the above embodiment, wavelengths of the laser source L for bonding the conductor 11 and the LED chip 12 and the laser source L for reducing the conductor 11 may be the same or may be different from each other.

### Second Embodiment

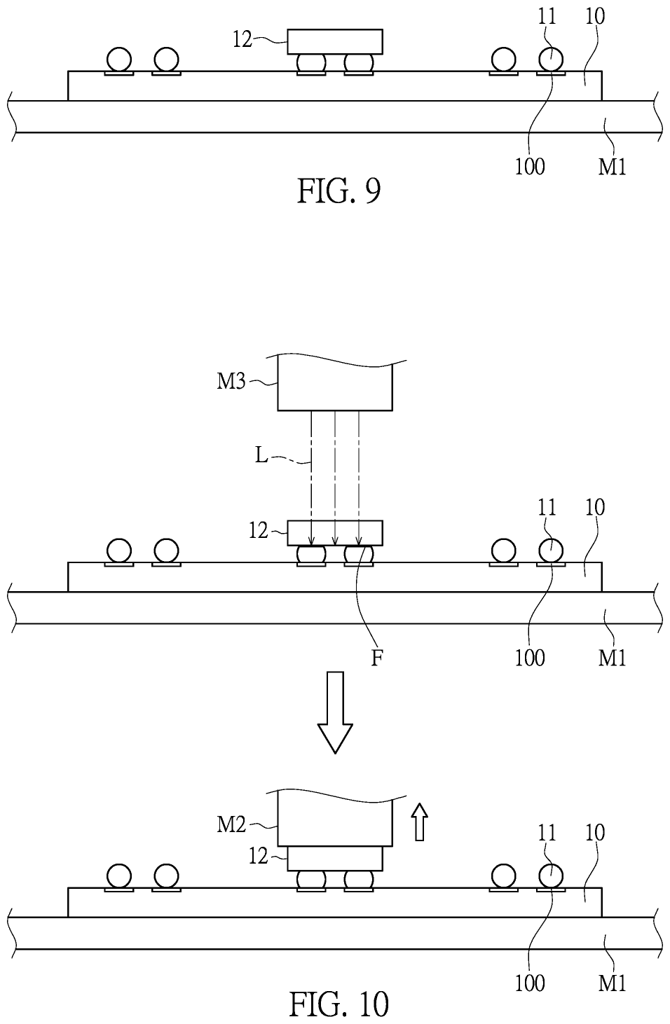

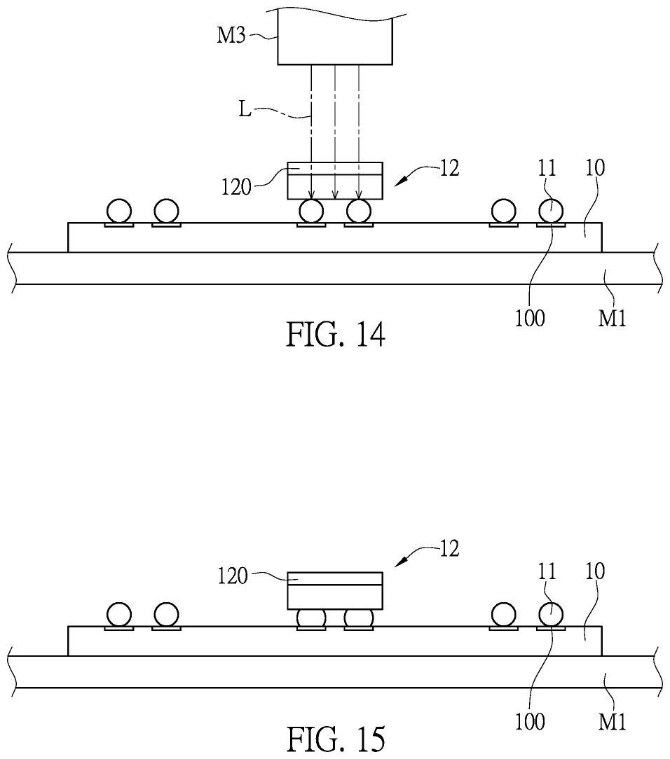

Referring to FIG. 14 to FIG. 15, together with FIG. 1 to FIG. 12, a second embodiment of the present disclosure provides an LED mounting method that is slightly similar to the mounting method of the LED chip of the first embodiment. Therefore, similar steps will not be repeated herein. Further, according to FIG. 5, FIG. 9 and FIG. 14 and FIG. 15, the difference between the second embodiment of the present disclosure and the first embodiment is that each of the LED chips 12 of the present embodiment can be a sub-millimeter light-emitting diode (Mini LED), including a base layer 120, an n-type conductive layer N, a light-emitting layer M through which the laser light source L passes, and a p-type conductive layer P that are disposed in a stacked arrangement. The base layer 120 is a sapphire material layer, the n-type conductive layer N may be an n-type gallium nitride material layer or an n-type gallium arsenide material layer, the light-emitting layer M is a multi-quantum well structure layer, and the p-type conductive layer P may be a p-type gallium nitride material layer or a p-type gallium arsenide material layer, but the present disclosure is not limited thereto. The base layer 120 may also be a quartz base layer, a glass base layer, a tantalum base layer, or a base layer of any material.

For example, as shown in FIG. 14, in a step similar to step S203 of the first embodiment, in the second embodiment of the present disclosure, a laser source L is generated through a laser source generation module M3 and is directed to each of the LED chips 12. When the laser source L is projected on the LED chip 12, the laser source L passes through the base layer 120, the n-type conductive layer N, the light-emitting layer M, and the p-type conductive layer P, so as to be projected on at least two conductors 11 of the circuit substrate 10.

Further, as shown in FIG. 15, in a step similar to step S204 of the first embodiment, the conductor 11 disposed between the LED chip 12 and the circuit substrate 10 of the second embodiment of the present disclosure is cured by irradiation of the laser source L so that the LED chip 12 is mounted on the circuit substrate 10. However, the above-mentioned examples are only one of the embodiments and the present disclosure is not limited thereto.

It should be noted that, as shown in FIG. 1 to FIG. 15, the present disclosure further provides an LED mounting device Z, which includes a carrier module M1, a pick and place module M2, and a laser source generation module M3. A laser source L generated by the laser source generation module M3 is directed to an LED chip 12 such that the laser source L passes through the LED chip 12 and is projected on at least two conductors 11. The conductor 11 is cured by irradiation of the laser source L, so that the LED chip 12 is mounted on the circuit substrate 10.

Further, as shown in FIG. 1 to FIG. 15, the present disclosure can also provide an LED mounting device Z, which includes: a carrier module M1, a pick and place module M2, and a laser source generation module M3. The carrier module M1 is used to carry a circuit substrate 10, and the circuit substrate 10 includes a plurality of conductive solder pads 100, and a plurality of conductors 11 that are respectively disposed on the conductive solder pads 100. The pick and place module M2 is for disposing a plurality of LED chips 12 on the circuit substrate 10, and each of the LED chips 12 is disposed on the at least two conductors 11. A laser source L generated by the laser source generation module M3 is directed to each of the LED chips 12 such that the laser source L passes through the LED chip 12 and is projected on the at least two conductors 11. The conductor 11 disposed between the LED chip 12 and the circuit substrate 10 of the second embodiment of the present disclosure is cured by irradiation of the laser source L, so that the LED chip 12 is mounted on the circuit substrate 10. The conductor 11 disposed between the LED chip 12 and the circuit substrate 10 is cured by the irradiation of the laser source L, so that the LED chip 12 is mounted on the circuit substrate 10.

### Third Embodiment

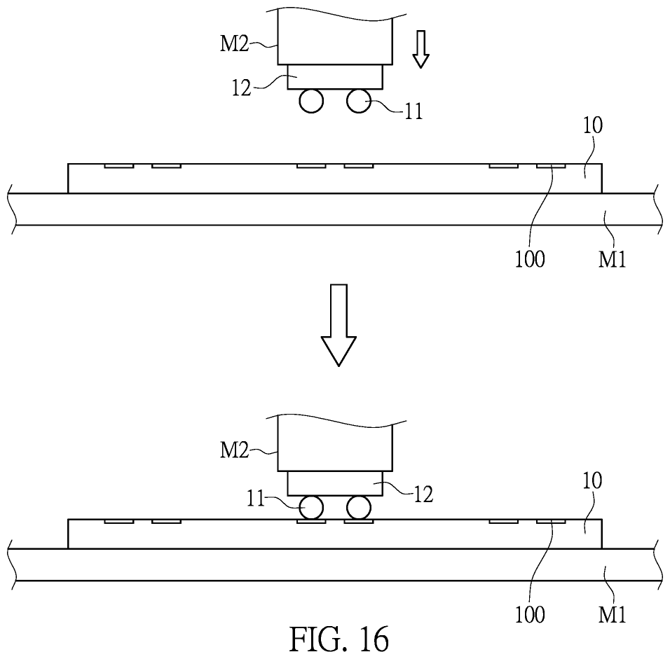

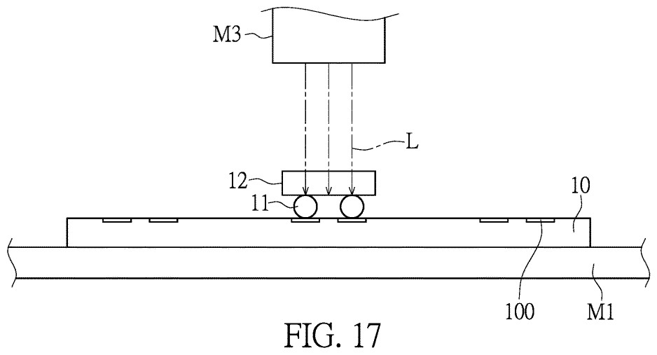

Referring to FIG. 16 and FIG. 17, together with FIG. 1 to FIG. 12, an LED mounting method according to a third embodiment of the present disclosure is slightly similar to that of the first embodiment. Therefore, similar steps will not be repeated herein. Further, according to FIG. 5, FIG. 9 and FIG. 14 and FIG. 15, the difference between the third embodiment of the present disclosure and the first embodiment is that the present embodiment further includes: disposing at least two conductors 11 on each of the LED chips 12 (step S201B). For example, in step S201B of the present disclosure, the at least two conductors 11 may be disposed on each of the LED chips 12, and the conductor 11 may be a solder ball or other structures made of an electrically conductive material. However, the present disclosure is not limited thereto.

Next, as shown in FIG. 1 to FIG. 9, FIG. 16 and FIG. 17, the plurality of LED chips 12 are placed on the circuit substrate 10 by the pick and place module M2, and the at least two conductors 11 of each of the LED chips 12 correspond to the conductive solder of the circuit substrate 10. Then, the laser source L generated by the laser source generation module M3 is directed to the LED chip 12. When the conductor 11 disposed between the LED chip 12 and the circuit substrate 10 is irradiated by the laser source L, the conductor 11 would be softened, so as to establish a connection with the circuit substrate 10. Finally, after the conductor 11 is cured, the LED chip 12 is mounted on the circuit substrate 10 so as to be electrically connected to the circuit substrate 10 through the conductor 11.

In conclusion, one of the beneficial effects of the present disclosure is that the LED mounting method of the present disclosure has the technical features of “providing a circuit substrate 10 which includes a plurality of conductive solder pads 100”, “respectively disposing a plurality of conductors 11 on the conductive solder pads 100”, “disposing a plurality of LED chips 12 on the circuit substrate 10”, “disposing each of the LED chips 12 on at least two conductors 11”, “directing a laser source L generated by a laser source generation module M3 to each of the LED chip 12 so that the laser source L passes through the LED chip 12 and is projected on at least two conductors 11” and ““the conductor 11 disposed between the led chip 12 and the circuit substrate 10 is cured by irradiation of the laser source L”, so that the led chip 12 is mounted on the circuit substrate 10.

Another beneficial effect of the present disclosure is that the LED mounting device Z of the present disclosure has the technical features of “a carrier module M1 for carrying a circuit substrate 10, the circuit substrate 10 including a plurality of conductive solder pads 100, and a plurality of conductors 11 being respectively disposed on the conductive solder pads 100”, “a laser source L generated by a laser source generation module M3 being directed to each of the led chip 12 so that the laser source L passes through the led chip 12 and is projected on the at least two conductors 11” and “the conductor 11 disposed between the led chip 12 and the circuit substrate 10 being cured by irradiation of the laser source L” so that the led chip 12 is mounted on the circuit substrate 10.

Still another beneficial effect of the present disclosure is that the LED mounting device Z of the present disclosure has the technical features of “the LED mounting device Z including a carrier module M1, a pick and place module M2 and a laser source generation module M3” and “a laser source L generated by the a laser source generation module M3 being directed to an LED chip 12 such that the laser source L passes through the led chip 12 and is projected on at least two conductors 11, and the conductor 11 is cured by irradiation of the laser source L” so that the led chip 12 is mounted on the circuit substrate 10.

Furthermore, the LED mounting method and device provided by the present disclosure has the above technical features that the conductor 11 is directly irradiated by the layer source L through the base layer 120, the n-type conductive layer N, the light-emitting layer M, and the p-type conductive layer P to perform die bonding process of the LED chip 12.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An LED mounting method, comprising:
providing a circuit substrate including a plurality of conductive solder pads;
disposing a plurality of LED chips on the circuit substrate, each of the LED chips being disposed on at least two conductors;
directing a laser source generated by a laser source generation module to each of the LED chips such that the laser source passes through the LED chip and is projected on at least two of the conductors; and
curing the conductor disposed between the LED chip and the circuit substrate by the laser source such that the LED chip is mounted on the circuit substrate.

2. The LED mounting method according to claim 1, wherein each of the LED chips includes an n-type conductive layer, a light-emitting layer through which the laser source passes, and a p-type conductive layer that are disposed in a stacked arrangement; the n-type conductive layer is an n-type gallium nitride material layer or an n-type gallium arsenide material layer, the light-emitting layer is a multi-quantum well structure layer, and the p-type conductive layer is a p-type gallium nitride material layer or a p-type gallium arsenide material layer; wherein the irradiation area of the laser source only covers one conductor or one LED chip, and the intensity of the laser source generated by the laser source generation module can be adjusted; wherein the laser source does not pass through the circuit substrate, but only passes through the LED chip.

3. The LED mounting method according to claim 1, wherein each of the LED chips includes a base layer, an n-type conductive layer, a light-emitting layer through which the laser source passes, and a p-type conductive layer that are disposed in a stacked arrangement; the base layer is a sapphire base layer, the n-type conductive layer is an n-type gallium nitride material layer or an n-type gallium arsenide material layer, the light-emitting layer is a multi-quantum well structure layer, and the p-type conductive layer is a p-type gallium nitride material layer or a p-type gallium arsenide material layer; wherein the irradiation area of the laser source covers only one conductor or one of the LED chips, and the intensity of the laser source generated by the laser source generation module can be adjusted; wherein the laser source does not pass through the circuit substrate, but only passes through the LED chip.

4. The LED mounting method according to claim 1, wherein after the step of providing the circuit substrate, the method further includes: disposing a plurality of the conductors on the conductive solder pads, or placing at least two conductors on each of the LED chips; wherein, after the step of mounting the LED chip on the circuit substrate, the method further includes: directing the laser source generated by the laser source generation module to the contact interface of the LED chip and the conductor, such that a connection strength between the LED chip and the conductor is reduced, so that the LED chip is easily removed from the circuit substrate.

5. An LED mounting device, comprising:
a carrier module for carrying a circuit substrate, the circuit substrate including a plurality of conductive solder pads, and a plurality of conductors being respectively disposed on the conductive solder pads;
a pick and place module for disposing a plurality of LED chips on the circuit substrate, each of the LED chips being disposed on at least two of the conductors; and
a laser source generation module, the generated laser source being directed to each of the LED chips, such that the laser source passes through the LED chip and is projected on at least two of the conductors;
wherein the conductor disposed between the LED chip and the circuit substrate is cured by irradiation of the laser source, so that the LED chip is mounted on the circuit substrate.

6. The LED mounting device according to claim 5, wherein each of the LED chips includes an n-type conductive layer, a light-emitting layer through which the light source passes, and a p-type conductive layer that are disposed in a stacked arrangement; the n-type conductive layer is an n-type gallium nitride material layer or an n-type gallium arsenide material layer, the light-emitting layer is a multi-quantum well structure layer, and the p-type conductive layer is a p-type gallium nitride material layer or a p-type gallium arsenide material layer; wherein the irradiation area of the laser source only covers one conductor or one LED chip, and the intensity of the laser source generated by the laser source generation module can be adjusted; wherein the laser source does not pass through the circuit substrate, but only passes through the LED chip.

7. The LED mounting device according to claim 5, wherein each of the LED chips includes a base layer, an n-type conductive layer, a light-emitting layer through which the laser source passes, and a p-type conductive layer that are disposed in a stacked arrangement; the base layer is a sapphire base layer, the n-type conductive layer is an n-type gallium nitride material layer or an n-type gallium arsenide material layer, the light-emitting layer is a multi-quantum well structure layer, and the p-type conductive layer is a p-type gallium nitride material layer or a p-type gallium arsenide material layer; wherein the irradiation area of the laser source covers only one conductor or one of the LED chips, and the intensity of the laser source generated by the laser source generation module can be adjusted; wherein the laser source does not pass through the circuit substrate, but only passes through the LED chip.

8. An LED mounting device, comprising a carrier module, a pick and place module, and a laser source generation module; wherein a laser source generated by the laser source generation module is directed to an LED chip, so that the laser source passes through the LED chip and is projected on at least two conductors, and the conductor is cured by irradiation of the laser source such that the LED chip is mounted on a circuit substrate.

9. The LED mounting device according to claim 8, wherein each of the LED chips includes an n-type conductive layer, a light-emitting layer through which the light source passes, and a p-type conductive layer that are disposed in a stacked arrangement; the n-type conductive layer is an n-type gallium nitride material layer or an n-type gallium arsenide material layer, the light-emitting layer is a multi-quantum well structure layer, and the p-type conductive layer is a p-type gallium nitride material layer or a p-type gallium arsenide material layer; wherein the irradiation area of the laser source only covers one conductor or one LED chip, and the intensity of the laser source generated by the laser source generation module can be adjusted; wherein the laser source does not pass through the circuit substrate, but only passes through the LED chip.

10. The LED mounting device according to claim 8, wherein each of the LED chips includes a base layer, an n-type conductive layer, a light-emitting layer through which the light source passes, and a p-type conductive layer that are disposed in a stacked arrangement; the base layer is a sapphire base layer, the n-type conductive layer is an n-type gallium nitride material layer or an n-type gallium arsenide material layer, the light-emitting layer is a multi-quantum well structure layer, and the p-type conductive layer is a p-type gallium nitride material layer or a p-type gallium arsenide material layer; wherein the irradiation area of the laser source covers only one conductor or one of the LED chips, and the intensity of the laser source generated by the laser source generation module can be adjusted; wherein the laser source does not pass through the circuit substrate, but only passes through the LED chip.
